(19) United States
(12) Patent Application Publication
(10) Pub. No.: US 2006/0139109 A1
(43) Pub. Date: Jun. 29, 2006

(54) PLL-based frequency synthesizer

(75) Inventors: Alain Oustaloup, Talence (FR); Yann Deval, Bordeaux (FR); Didier Belot, Rives (FR); Pierre Melchior, Andernos (FR); Jean-Baptiste Begueret, Talence (FR); Franck Badets, Meylan (FR); Vincent Lagareste, Brignoud (FR)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics SA, Montrouge (FR)

(21) Appl. No.: 11/235,787

(22) Filed: Sep. 27, 2005

(30) Foreign Application Priority Data
Sep. 30, 2004 (FR) 04 10367

(51) Int. Cl. H03L 7/00

(52) U.S. Cl. 331/17

(57) ABSTRACT

The frequency synthesizer includes a phase-locked loop (PLL). The PLL includes an oscillator controlled to deliver an output signal at a predefined output frequency, a variable frequency divider to convert the output signal into a divided-frequency signal, a phase comparator to produce a signal measuring a phase difference between the divided-frequency signal and a reference signal at a reference frequency, and a loop filter to control the oscillator on the basis of the measurement signal. To increase the speed of convergence of the synthesizer if the set point is changed, the loop filter of the PLL is a fractional, i.e. non-integer, order low-pass filter.

### FIELD OF THE INVENTION

The present invention relates to phase-locked loop (PLL)-based frequency synthesizers, and in particular, to radio frequency (RF) transmitters and/or receivers including PLL-based frequency synthesizers.

### BACKGROUND OF THE INVENTION

A PLL conventionally comprises a voltage-controlled oscillator (VCO) producing a high frequency signal, a frequency divider (also called loop divider) converting the high frequency signal into a divided-frequency signal, a phase comparator producing a signal measuring a phase difference between the divided-frequency signal and a signal at a reference frequency, and a low-pass filter (also called loop filter) to which the measurement signal is applied and the output of which controls the VCO.

In its application to frequency synthesis, the value of the division factor applied by the frequency divider is adapted to obtain a set point value of the VCO output signal frequency. In practice, the following equation applies:
Fout=N×Fref
in which Fout is the frequency of the VCO output signal, Fref is the PLL reference frequency, and N is the division ratio (integer) of the loop divider.

The bandwidth of the PLL corresponds to that of a low-pass filter. It determines the speed of the response to a change of set point. It is an important factor in the performance of the synthesizer incorporating the PLL. In practice, the greater the bandwidth of the PLL, the faster the synthesized frequency stabilizes on a change of radio channel, for example.

Furthermore, the bandwidth requires the phase noise of the reference signal source (which is often better than the phase noise of the VCO at low frequencies) to be monitored within this frequency band. Consequently, the greater the bandwidth, the lower the phase noise of the PLL, and therefore of the synthesizer, at low frequencies. Consequently, it is desirable to widen the bandwidth of the PLL, to optimize the speed and phase noise of the frequency synthesizer incorporating it.

The bandwidth of the PLL is mainly determined by the bandwidth of the loop filter and by the open loop gain of the PLL. However, the bandwidth of the loop filter is chosen so as to filter out the spurious line generated by the phase comparator at the reference frequency.

To ensure the stability of the loop, a

bandwidth equal to or less than Fref/10 or even Fref/15, is suitable for the loop filter.

Compliance with this criterion ensures good stability and good rejection of the spurious at Fref generated by the phase comparator.

The bandwidth of the PLL therefore depends directly on the reference frequency Fref of the PLL. By choosing a higher reference frequency Fref, this bandwidth can be increased. However, the reference frequency also defines the synthesis pitch, in other words, for example, the frequency interval separating two adjacent radio channels (for example, 200 kHz for GSM). The bandwidth of the PLL therefore depends on the reference frequency, which in turn depends on the target standards (through the synthesis pitch).

In the prior art, an approach has already been proposed to increase Fref without adversely affecting the synthesis pitch, in the form of the fractional (i.e. non-integer) PLL. The fractional PLL represents a compromise, by replacing the frequency divider with integer division ratio with a fractional frequency divider (non-integer division). Thus, the reference frequency can be increased (for example, from 200 kHz to 10 MHz) while retaining the same synthesis pitch (200 kHz in the example).

A fractional PLL uses a fractional loop divider, based on the use of a Sigma-Delta modulator, the output of which drives the input controlling the division ratio of the divider. Such a fractional divider divides by N during a predefined number P−1 of reference signal cycles and by N+1 during one cycle of the reference signal. Then, on average, the following equation applies:

$$Fout = Fref \times ( N + \frac{1}{P} )$$

The synthesis pitch becomes less than the reference frequency, since it is approximately equal to

$$Fref \times ( \frac{1}{{P}^{2}} ) .$$

For an identical synthesis pitch, a higher reference frequency can therefore be used, which consequently means that the bandwidth of the PLL can also be increased. This frequency is, however, obtained only as an average, over N periods of the reference signal, which has the direct consequence of producing spurious at the output. These spurious limit the usable bandwidth of the fractional PLL. Of course, the Sigma-Delta modulator formats the noise in the high frequencies, but the cut-off frequency of the loop filter has to be lowered to filter it. For this reason, the fractional PLL is not entirely satisfactory from the point of view of the problem raised.

### SUMMARY OF THE INVENTION

One object of the present invention is therefore increase the speed of convergence of a frequency synthesizer when the set point is modified, without using a fractional PLL.

To this end, the proposed approach is to increase the bandwidth of the loop filter of the PLL while retaining the same rejection of the spurious generated by the phase comparator at the reference frequency.

The invention thus provides a frequency synthesizer comprising a phase-locked loop (PLL), in which the PLL comprises an oscillator controlled to deliver an output signal at a predefined output frequency, a variable frequency divider to convert the output signal into a divided-frequency signal, a phase comparator to produce a signal measuring a phase difference between the divided-frequency signal and a reference signal at a reference frequency, and a loop filter to control the oscillator on the basis of the measurement signal. Furthermore, the loop filter of the phase-locked loop is a fractional, i.e. non-integer, low-pass filter.

By convention, the order of a filter is used here with reference to the slope of the attenuation that it introduces for high frequencies, independently of its number of poles. Normally, only integer type first, second, third, etc order filters are used, respectively introducing an attenuation of −20 dB/dec decibels/decade), −40 dB/dec, −60 dB/dec, etc, because they can be produced simply. Stated otherwise, only filters having an attenuation that is an integer multiple of −20 dB/dec are used.

As will be explained in the detailed description, the non-integer order of the loop filter of the PLL of the synthesizer according to the invention is used to obtain an attenuation for high frequencies that is between −20 dB/dec and −40 dB/dec. Thus, the bandwidth of the loop filter can be increased without incurring PLL instability.

The division ratio of the frequency divider can be a predefined integer number, that is, the PLL can be an integer PLL. Stated otherwise, the invention applies to synthesizers for which the PLL is not necessarily a fractional PLL. The PLL can be a charge pump PLL. The phase comparator then comprises: on the one hand a phase/frequency detector having a first input designed to receive the reference signal and a second input designed to receive the divided-frequency signal, and two outputs delivering binary output signals; and, on the other hand, a charge pump for delivering a charge current from said binary output signals delivered by the phase/frequency detector. This charge current is the abovementioned measurement signal.

In one embodiment, the loop filter comprises a first integer order filtering stage followed by a second filtering stage of fractional order between 0 and 1. In an embodiment, the order of the second stage of the loop filter is at most equal to ½. A ½ order filter introduces an attenuation equal to −10 dB/dec and a phase difference equal to −45°. When the first stage is first order, and it therefore introduces an attenuation of −20 dB/dec and a phase difference of −90°, the result is a phase margin (estimated in open loop mode, in other words at the VCO output), of at least −45°. Such a phase margin is considered sufficient to ensure stability. Advantageously, approaches for simply obtaining a fractional order filter between 0 and 1 are known. For example, the second stage of the loop filter can comprise a recursive parallel arrangement of low-pass cells.

In an embodiment, the low-pass cells are series RC cells. This embodiment is particularly advantageous when the first stage of the loop filter is a truncated first order RC filter (in other words having two poles). In practice, the alignment of the frequency response of the two stages of the loop filter is facilitated.

### BRIEF DESCRIPTION OF THE DRAWINGS

Other features and advantages of the invention will become apparent on reading the description that follows. This is purely illustrative and should be read in light of the appended drawings in which:

FIG. 1 is a diagram of a PLL according to the prior art;

FIG. 2 is a diagram of an exemplary embodiment of a truncated first order filter (filter with two poles);

FIG. 3 gives gain and phase diagrams (Bode diagrams) of the filter of FIG. 2;

FIG. 4 illustrates the maximum bandwidth of a PLL with the filter of FIG. 2 as the loop filter;

FIG. 5 is a diagram of an embodiment of a frequency synthesizer according to the invention, using a charge pump PLL (CP-PLL);

FIG. 6 is a diagram of an embodiment of the PLL loop filter of the synthesizer of FIG. 5, comprising a first integer order filtering stage followed by a second fractional (non-integer) order filtering stage;

FIG. 7 is the gain diagram of only the second stage of FIG. 6;

FIG. 8 is the gain diagram of the filter of FIG. 6 (complete);

FIG. 9 gives a comparison between the gain diagram of the filter of FIG. 2 and that of FIG. 6;

FIG. 10 gives a comparison between the gain and phase diagrams, in open loop mode, of the PLLs of FIG. 1 and FIG. 5.

### DETAILED DESCRIPTION OF THE PREFERRED EMBODIMENTS

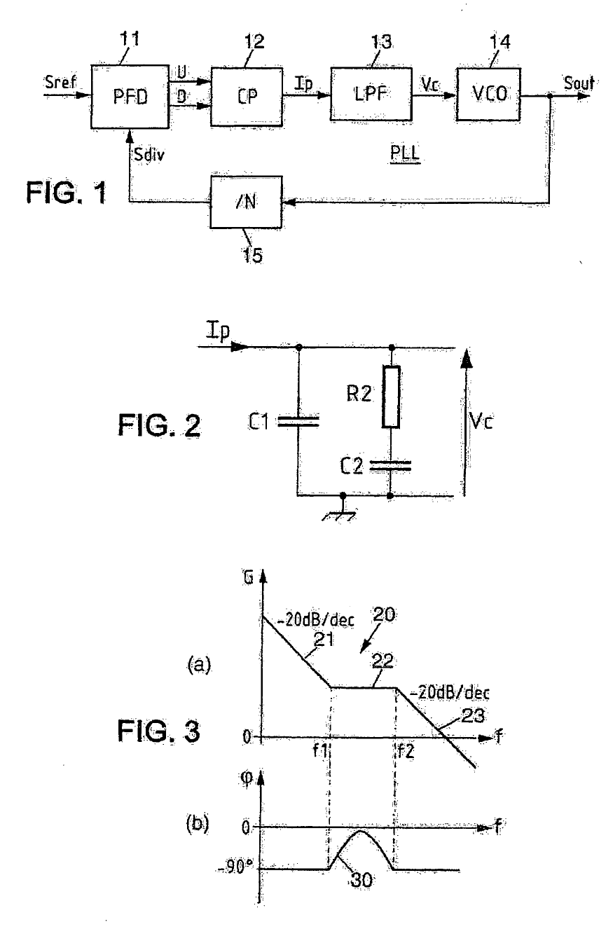

With reference to FIG. 1, a PLL used in a frequency synthesizer according to the prior art comprises a VCO 14 delivering a radiofrequency signal Sout, the frequency Fout of which is, for example, of the order of a few hundred MHz. This signal is addressed to a frequency divider 15 applying a variable division ratio N. By modifying the set point associated with N, the frequency of the output signal Sout is changed.

In the example considered, the PLL is a charge pump PLL (CP-PLL), which is one of the most widely used PLL structures. The divided-frequency signal Sdiv obtained from the frequency divider 15 is addressed to an input of a phase/frequency detector (PFD) 11 which also receives a reference signal Sref produced from a crystal oscillator. The frequency Fref of the signal Sref is, for example, approximately 10 MHz. To obtain a predefined frequency Fvco at the VCO 14 output, N=Fout/Fref is applied.

The PFD 11 has an output signal made up of two binary components U and D. A charge pump 12 (CP) receives these two components to produce a charge current IP at an input node of a low-pass filter (LPF)

13. The current Ip constitutes a signal measuring the phase difference between the signals Sdiv and Sref. The filtered voltage Vc produced by this filter 13 is used to control the frequency of the VCO 14.

The diagram of FIG. 2 illustrates an exemplary embodiment of a truncated first order low-pass filter which is conventionally used as the loop filter of the PLL. Such a filter has two poles but presents an attenuation of −20 dB/dec. The filter is a current-voltage converter, producing the voltage Vc according to the current Ip. More specifically, it comprises a capacitor C1 between the input of the filter and the ground terminal, in parallel with a series RC cell, which is in turn formed by a resistor R2 and a capacitor C2 (on the ground terminal side). The transfer function (according to the Laplace variable p) is given by:

$$F ( p ) = \frac{1 + {τ}_{1} p}{p ( 1 + {τ}_{2} p )}$$

$$in which {τ}_{1} = R2 \times C2 and {τ}_{2} = R2 \times \frac{C2 \times C1}{( C2 + C1 )}$$

In the description that follows, f1 and f2 are used to denote the cut-off frequencies of this filter given by

$$f1 = \frac{1}{2 π . {τ}_{1}} and f2 = \frac{1}{2 π . {τ}_{2}} .$$

The gain diagram and the phase diagram (frequency response) of this filter are given in FIG. 3. The curve of the gain 20 (top part of FIG. 3) comprises a portion 21 having a slope of −20 dB/dec between the zero frequency and the cut-off frequency f1, then a flat portion 22 (0 dB/dec) between the cut-off frequencies f1 and f2, and finally a portion 23 again having a slope of −20 dB between f2 and the high frequencies.

The portion 21 provides the gain at the low frequencies (where the filter behaves as an integrator), which ensures the stability of the PLL. The portion 22 is the one in which the phase difference is introduced, as can be seen on the phase curve 30 (at the bottom of FIG. 3). Finally, the portion 23 provides high frequency rejection.

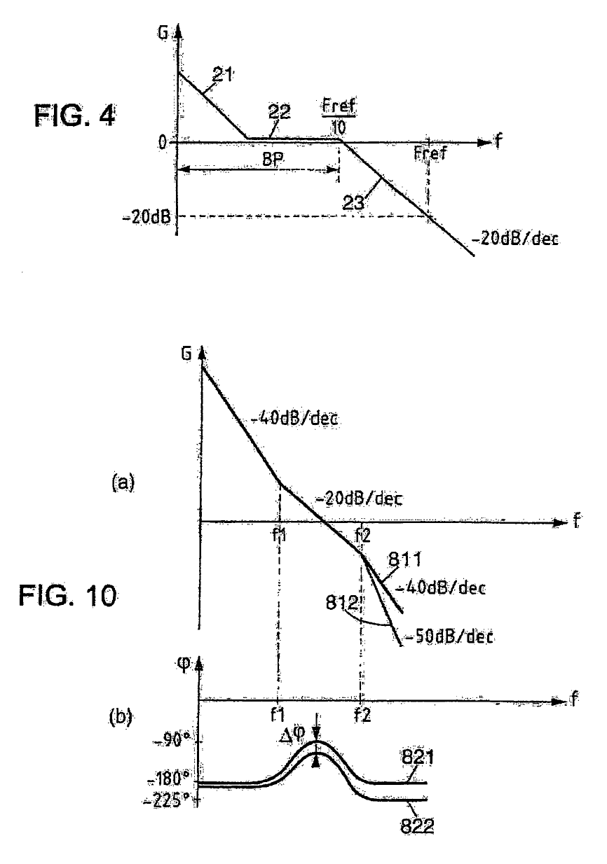

When such a filter is used as a loop filter of a PLL, the constraint is the rejection of the spurious line generated at the reference frequency Fref by the PFD. To have a rejection of −20 dB, it is essential to have a filter cut-off frequency f2 at Fref/10 , given the slope of −20 dB/dec, as illustrated in FIG. 4. The bandwidth BW of the PLL is therefore the band [O;Fref/10].

To ensure the stability of the system, it is essential for the open loop mode phase to be strictly greater than −180° when the gain G is zero. In practice, a phase margin is provided, for example of −450. There should therefore be a phase difference φ at the output of the VCO of no more than −135°, when the gain G is zero, given that it can be seen that the VCO introduces an additional slope of −20 dB/dec and an additional phase difference of −90° (it behaves as a first order low-pass filter).

In other words, the order of the filter cannot simply be doubled (to have a slope of −40 dB/dec and therefore the same rejection of Fref with a greater bandwidth) without significantly altering the phase margin of the system and thus causing an instability and therefore limiting the bandwidth that can actually be used. In practice, if the phase difference introduced by a first order filter (with a slope of −20 dB/dec) is equal to −90°, that introduced by a second order filter (with a slope of −40 dB/dec) is equal to −180°.

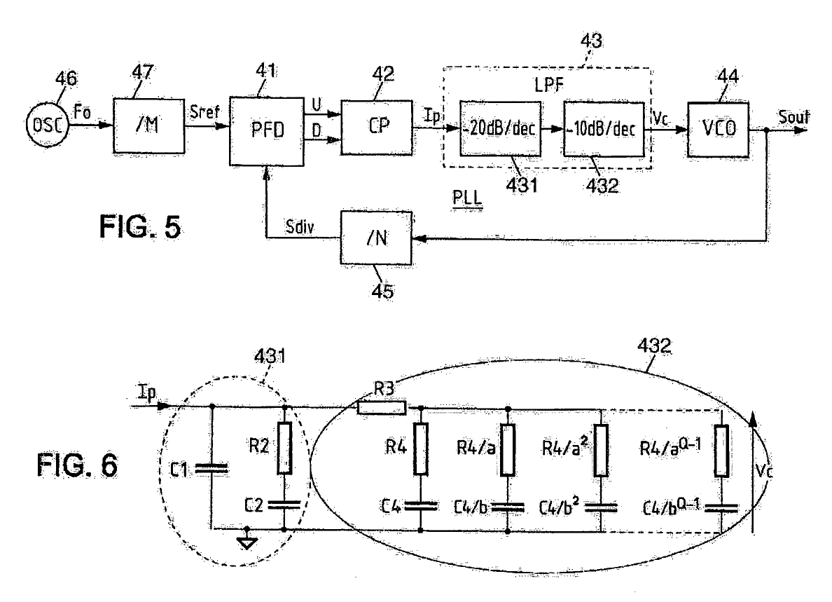

This is why the invention proposes to use, as the loop filter of the synthesizer's PLL, a fractional order filter greater than 1 by a non-integer value of between 0 and 1. An exemplary embodiment of the frequency synthesizer according to the invention is given by the diagram in FIG. 5.

The synthesizer comprises a PLL, for example a CP-PLL comprising a PFD 41, a charge pump 42, a loop filter 43, a VCO 44 and a frequency divider 45 arranged in the same way as the corresponding elements, respectively 11 to 15, of the PLL of FIG. 1. This arrangement is not therefore described again in detail.

The reference signal Sref is generated from a crystal oscillator 46 and a frequency divider 47. If the reference frequency of the oscillator 46 is denoted Fo and the division ratio of the divider 47 is denoted M, the following equation applies:
Fo=M×Fref

Stated otherwise, the frequency Fout of the output signal and of the frequency synthesizer is given by the equation:

$$Fout = \frac{N}{M} \times Fo$$

According to the invention, the order of the loop filter 43 is fractional, that is, non-integer. There now follows a description of an embodiment of such a fractional filter.

FIG. 6 illustrates an exemplary embodiment of the non-integer order low-pass filter 43. In this example, the order of the loop filter is equal to 1.5. The filter 43 comprises an first integer order filtering stage 431, and a second non-integer or fractional order filtering stage 432 of order between 0 and 1. The stage 431 is produced in the conventional way. It is, for example, a truncated first order low-pass filter, in accordance with the prior art illustrated by FIG. 2.

The stage 432 is advantageously a recursive parallel arrangement of series RC cells. Such an arrangement is particularly advantageous because it uses only passive, resistor and capacitor components. However, it can be used only to obtain a fractional order of between 0 and 1. This is why the stage 432 is associated with the stage 431 (first order) or with any other integer order stage (second, third, fourth or above) when a fractional order greater than or equal to 2 is required.

With reference to the diagram in FIG. 6, the stage 432 of the loop filter comprises a resistor R3 in series between the input and the output of the filter, followed by a predefined number Q of series RC cells connected in parallel between the output of the filter and ground, where Q is an integer strictly greater than unity. Each series RC cell comprises a resistor of value R4/aⁱ and a capacitor of value C4/bⁱ, in which: R4 is a predefined resistance value; C4 is a predefined capacitance value; a and b are predefined real numbers; and i is an integer number respectively between 0 and Q−1.

Thus, 1/a and 1/b are used respectively to denote the constant ratios between the resistors and the capacitors of two consecutive cells. The numbers a and b are also called recursive factors. These recursive factors are here considered to be greater than unity.

Each cell forms, with the resistor R3, a truncated first order low-pass filter (but with two poles), for which the cut-off frequencies f1ᵢ and f2ᵢ are given, respectively, by:

$${f1}_{i} = \frac{1}{2 π \times R3 \times C4 / {b}^{i}}$$

$${f2}_{i} = \frac{1}{2 π \times R4 / {a}^{i} \times C4 / {b}^{i}}$$

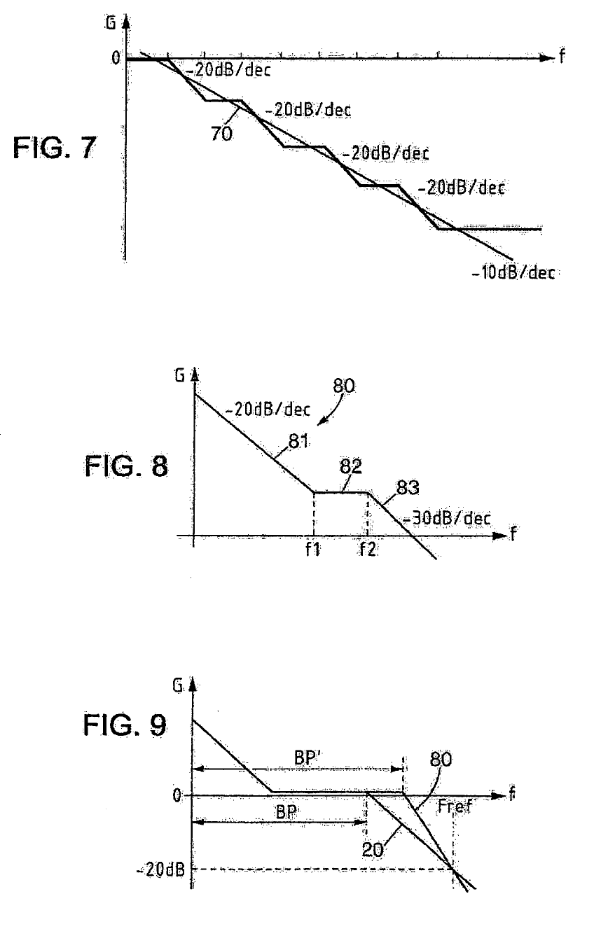

By choosing the number Q and the recursive factors a and b in an appropriate manner, it is possible to obtain for the stage 432 a frequency response of the type illustrated by the gain diagram of FIG. 7. As can be seen, the gain diagram is a result of the contribution of each cell. The smoothing of the staircase treads that make up this gain diagram can be represented by a straight line 70, called “gain smoothing straight line”. When the differences between the cut-off frequencies f1ᵢ and f2ᵢ of each cell are constant, as in the case represented, the slope of this straight line is equal to −10 dB/dec.

For more complete information on the frequency analysis of the arrangement 432 of FIG. 6, and for other examples of recursive parallel low-pass cell arrangements, the reader should refer to the book “La dérivation non entiére, theorie et applications”, Chapter 5, by Alain OUSTALOUP, Ed. HERMES, 1995.

It will be noted that the application of a non-integer order filter in a PLL used for frequency demodulation is described in the book “Systemes Asservis Linéaires d'Ordre Fractionnaire”, Part 4, Chapter II, by Alain OUSTALOUP, Ed. MASSON, 1983.

The application of a half-order (i.e., of order equal to ½) low-pass filter to the production of a PLL-based sinusoidal oscillator used in frequency demodulation receivers is also mentioned in French patent application number 2 444 362 by Alain OUSTALOUP, and has also been the subject of the published article entitled “Fractional Order Sinusoidal Oscillators: Optimization and Their Use in Highly Linear FM Modulation”, A. OUSTALOUP, IEEE TRANSACTIONS ON CIRCUITS AND SYSTEMS, Vol. Cas-28, No 10, October 1981”.

Its application in the integer PLL-based frequency synthesizers represents an original alternative to the previously known approaches for increasing the adaptation speed of the PLL, such as fractional synthesis with the use of a Sigma-Delta modulator.

FIG. 8 gives the gain diagram of the loop filter 43 produced in accordance with the example in FIG. 6. In this example, furthermore, the cut-off frequency of the filtering stage 432 is merged with the cut-off frequency f2 of the filtering stage 431. For this purpose, the following equation applies:

$$R4 \times C4 = R2 \times \frac{C2 \times C1}{C2 + C1}$$

As can be seen, the gain diagram of the fractional order filter 43 is a curve 80 comprising a portion 81 with a slope of −20 dB/dec for the frequencies below f1, a flat portion (at 0 dB/dec) 82 between the frequencies f1 and f2, and a portion 83 with a slope at −30 dB/dec between the frequency f2 and a certain frequency above f2 (not represented) which depends on the number Q of low-pass cells connected in parallel in the stage 432. After this frequency, the attenuation is again equal to 0 dB/dec.

FIG. 9 gives a comparison between the gain diagram of the integer order filter given in FIG. 2 (curve 20) and that of the fractional order filter given in FIG. 6 (curve 80). It can be seen that, to obtain the same attenuation of −20 dB/dec at the frequency Fref introduced by the PFD of the PLL, the fractional order filter provides for a bandwidth BP′ which is greater than the bandwidth BP provided by the integer order filter. This means that the cut-off frequency f2 of the filter 43 in FIG. 5 can be adjusted to a value greater than that of the filter 13 in FIG. 1. The result is a faster convergence of the frequency synthesizer if the set point associated with the division ratio N is changed.

The gain and phase diagrams respectively represented in the top and bottom parts of FIG. 10 show the advantage of the invention in terms of system stability. This stability is determined by the open loop mode phase φ (evaluated at the VCO output) when the gain G passes through 0. It should be remembered that the VCO introduces an additional slope of −20 dB/dec which is added to those indicated above in light of the diagram in FIG. 8, and an additional phase difference of −90°. The result is that, above the cut-off frequency f2, the slope of the curve 811 corresponding to the gain diagram of the filter of FIG. 2 is equal to −40 dB/dec, and that of the curve 812 corresponding to the gain diagram of the filter of FIG. 6 is equal to −50 dB/dec. Similarly, the phase for the filter of FIG. 2 (curve 821) is equal to −1800 above the frequency f2, whereas the phase of the filter of FIG. 6 (curve 822) is equal to −225° above f2.

In other words, the ½ fractional order of the second filtering stage 432 of the loop filter 43 introduces an additional phase difference of −45° for high frequencies, above the cut-off frequency f2. Nevertheless, the phase difference Δφ introduced between the cut-off frequencies f1 and f2, when the gain G is cancelled, is limited to approximately 5° or 6°.

This phase difference does not significantly affect the phase margin provided to ensure stability. This reflects the advantage obtained by the use of a fractional order loop filter, in this case equal to 1.5, in the PLL of the frequency synthesizer.

That which is claimed is:

1. Frequency synthesizer comprising a phase-locked loop (PLL) wherein said phase-locked loop comprises:
an oscillator (44) controlled to deliver an output signal (Sout) at a predefined output frequency (Fout), a variable frequency divider (45) to convert the output signal into a divided-frequency signal (Sdiv), a phase comparator (41, 42) to produce a signal (Ip) measuring a phase difference between the divided-frequency signal and a reference signal (Sref) at a reference frequency, and a loop filter (43) to control the oscillator on the basis of the measurement signal,
characterized in that the loop filter of the phase-locked loop is a non-integer order low-pass filter.

2. Frequency synthesizer according to claim 1, wherein the loop filter comprises a first integer order stage (431) followed by a second stage (432) of order between 0 and 1.

3. Frequency synthesizer according to claim 2, wherein the order of the second stage of the loop filter is at most equal to ½.

4. Frequency synthesizer according to claim 2, wherein the second stage of the loop filter comprises a parallel recursive arrangement of low-pass cells.

5. Frequency synthesizer according to claim 4, wherein the low-pass cells are series RC cells.

6. Frequency synthesizer according to claim 2, in which the first stage of the loop filter comprises a truncated first order low-pass filter.
